(19) United States
(12) Patent Application Publication
(10) Pub. No.: US 2013/0270977 A1
(43) Pub. Date: Oct. 17, 2013

(54) DISPLAY DEVICE AND ITS ASSEMBLY METHOD

(71) Applicant: COMPAL ELECTRONICS, INC., Taipei City (TW)

(72) Inventors: Juo-Ti CHEN, Taipei City (TW); Po-An LIN, Taipei City (TW); Kuo-Nan LING, Taipei City (TW); Yung-Hui CHEN, Taipei City (TW)

(21) Appl. No.: 13/854,940

(22) Filed: Apr. 1, 2013

Related U.S. Application Data
(60) Provisional application No. 61/620,422, filed on Apr. 4, 2012.

(51) Int. Cl. H05K 5/00; A47B 81/06

(52) U.S. Cl. CPC H05K 5/0017; A47B 81/06
USPC 312/7.2

(57) ABSTRACT

A display device and its assembly method are provided. The display device includes a panel module, a fixing frame and two hinge elements. The fixing frame is provided with two supports and two hinge brackets collectively assembled to be the fixing frame having a hollow portion therein, and each of the hinge brackets includes a placement surface and a hinge contact portion connected with one of the hinge elements. The panel module covers the hollow portion, and is secured on the fixing frame in which the panel module is supported by a placement surface.

### RELATED APPLICATIONS

This application claims priority to U.S. Provisional Application Ser. No. 61/620,422, filed Apr. 4, 2012, which is herein incorporated by reference.

### BACKGROUND

1. Field of Invention

The invention relates to a display device and its assembly method. More particularly, the invention relates to a display device assembled with hinge elements and its assembly method.

2. Description of Related Art

In recent years, since the portability of a portable computer is emphasized, thinning and weight lightening have come into design considerations of industry manufactures for improving the portable computer. However, when the design of thinning and weight lightening of the portable computer is performed, the trend is improving a frame of a display device to reduce the thickness of the display device while it is desired that the structural strength of the display device is not reduced, so that when the display device is subject to an impaction or a pressure from an external ambient object the fault of the display device on the portable computer can be avoided.

In the prior art, an assembly structure of a portable computer display panel is disclosed by a patent No. TWM 276250, which is filed on 12 May, 2005, as shown in FIG. 1-FIG. 3. FIG. 1 illustrates a rotating axis frame of a conventional display panel as same as FIG. 10 of the prior art, and only the reference numbers and the figure numbers are modified. FIG. 2 illustrates a perspective view of a first bracket and a first hinge of FIG. 1, as same as FIG. 4 of the prior art, and only the reference numbers and the figure numbers are modified. FIG. 3 illustrates a schematic view of the rotating axis frame of FIG. 1 assembled to a display panel, as same as FIG. 11 of the prior art, and only the reference numbers and the figure numbers are modified.

As shown in FIGS. 1 and 3, the rotating axis frame includes a first hinge 23, a first bracket 21, a second hinge 33, a second bracket 31 and a hard frame 1. The hard frame 1 covers the first bracket 21 and the second bracket 31.

As shown in FIG. 2, the first hinge 23 includes a main machine body fixing portion 232 and a first bracket fixing portion 233. The main machine body fixing portion 232 is used to connect to a main machine body (not shown). The first bracket fixing portion 233 is used to connect to the first bracket 21. The first bracket 21 includes a plurality of display panel connection portions 221, 222, 223 and 224 and a hinge fixing portion 225. The display panel connection portions 221, 222, 223 and 224 are used to connect to a side edge of a display panel (FIG. 3). The hinge fixing portion 225 is connected to the first bracket fixing portion 233. An outer edge of the first bracket 21 includes a plurality of hard frame fixing portions 211, 212 and 213 additionally. The hard frame fixing portions 211, 212 and 213 are used to connect to a first side edge 11 of the hard frame 1 (FIG. 3) and the structure of the second hinge 33 is as same as that of the first hinge 23. Therefore, it will not be described anymore herein.

As shown in FIG. 3, the assembly structure of the previous disclosure totally hides each fixing portion when matching with an upper cover 5 of the display panel by locking the hard frame 1 and the first bracket 21 and the second bracket 31, so as to provide a novel design which does not destroy the appearance. However, in the improvement for the rotating axis frame of the above-mentioned previous disclosure, the structural strength of the display device can be maintained by matching with the hard frame. Not only is the cost increased but also the volume of the display device is enlarged. An improvement space for the structural volume and thickness of the display device still exists.

From this, it can be seen that the assembly structure of the above-mentioned display panel still has inconvenience and disadvantage and it needs a further improvement. Therefore, at present, it is one of the important research and development subjects that how the above-mentioned inconvenience and disadvantage can be solved efficiently.

### SUMMARY

A technical aspect of the invention provides a display device used to improve a structural thickness of a display device efficiently and still maintain the original structural strength of the display device.

According to an embodiment of the invention, a display device includes a fixing frame, a panel module and two hinge elements. The fixing frame includes two first supports and two hinge brackets. The two first supports are configured in parallel. The two hinge brackets are configured in parallel collectively assembled with these first supports to be the fixing frame having a hallow portion therein. Each of the hinge brackets includes a first placement surface and a hinge contact portion. The hinge contact portion is located on an end of the hinge bracket. The panel module covers the hollow portion, and is secured on the fixing frame. The panel module covers the hollow portion, and is secured on the fixing frame, wherein a bottom surface of the panel module is supported by the first placement surface. The two hinge elements are connected to these hinge contact portions respectively.

In an embodiment of the invention, the panel module includes a display panel and a backlight module overlapped on each other and the backlight module is contacted with the first placement surface.

In an embodiment of the invention, the fixing frame further includes two second supports. The first supports and the second supports form a frame body together. The frame body includes a first surface and a second surface opposite to each other. The first surface contacts and supports the display panel. Each of the hinge brackets is overlapped on the second surface of the frame body.

In an embodiment of the invention, a portion of each hinge bracket extends outwards from the frame body. One of the hinge contact portions is located on this portion of the hinge bracket.

In an embodiment of the invention, a long axial edge of the first support extends a flange towards the hollow portion. The flange has a second placement surface. The second placement surface and the first placement surface both contact and support the backlight module. The second placement surface and the first placement surface coexist in the same plane height or different plane heights.

In an embodiment of the invention, each hinge bracket includes a first linear frame, a first high section differential surface and a first low section differential surface. The first high section differential surface is located on a side edge of the first linear frame far away from the hollow portion. The first low section differential surface is located on another side edge of the first linear frame between the hollow portion and the first high section differential surface. A long axis direction of the first low section differential surface is parallel to that of the first high section differential surface. The first high section differential surface contacts and supports the display panel and the first low section differential surface is a first placement surface.

In an embodiment of the invention, each hinge bracket includes a second linear frame, a second high section differential surface and a second low section differential surface. The second high section differential surface is located on a side edge of the second linear frame far away from the hollow portion. The second low section differential surface is located on another side edge of the second linear frame between the hollow portion and the second high section differential surface. A long axis direction of the second low section differential surface is parallel to that of the second high section differential surface. The second high section differential surface contacts and supports the display panel and the second low section differential surface is a second placement surface used to abut against and support the backlight module.

In an embodiment of the invention, each hinge bracket further includes two first embedding portions. The first embedding portions are configured oppositely on a one side of the first low section differential surface. Each support further includes two second embedding portions. The second embedding portions are oppositely configured on two ends of the second linear frame and the second embedding portions are just embedded into the first embedding portions.

In an embodiment of the invention, the first embedding portion and the second embedding portion embedded into each other are a dovetail tenon and a dovetail groove respectively.

In an embodiment of the invention, each hinge bracket further includes a connection side wall and a location open slot. The connection side wall is located in the first linear frame and is connected between the first high section differential surface and the first low section differential surface. The location open slot is located on the connection side wall used to locate multiple optical films of the backlight module.

In an embodiment of the invention, one of the hinge contact portions is located on an end of the first linear frame.

In an embodiment of the invention, the display device further includes a front cover. The front cover is assembled to a surface of the hinge bracket back towards the panel module.

In an embodiment of the invention, these hinge brackets are assembled in parallel on these first supports by a screw locking method or a hot-melting fixing method respectively.

According to an embodiment of the invention, a display device includes a frame body, two hinge brackets, a panel module and two hinge elements. The frame body includes two first supports and two second supports. The two first supports are configured in parallel. The two second supports are configured in parallel collectively assembled with these first supports to be the frame body having a first surface and a second surface opposite to each other. These hinge brackets are overlapped on the second surface of the frame body and work with the frame body to define a hollow portion. Each hinge bracket has a first placement surface and a hinge contact portion located on an end of the hinge bracket. The panel module covers the hollow portion, and is secured on the frame body. A bottom surface of the panel module is supported by these first placement surfaces. These hinge elements are connected to these hinge contact portions respectively.

In an embodiment of the invention, the panel module includes a display panel and a backlight module overlapped on each other and the backlight module is contacted with these first placement surfaces. The first surface of the frame body contacts and supports the display panel.

In an embodiment of the invention, a portion of each hinge bracket extends out of the frame body, and one of the hinge contact portions is located on the portion of the hinge bracket.

In an embodiment of the invention, each first support further includes two first embedding portions and each second support further includes two second embedding portions. One of the second embedding portions is just embedded into one of the first embedding portions.

In an embodiment of the invention, the first embedding portion and the second embedding portion embedded into each other are a dovetail tenon and a dovetail groove respectively.

In an embodiment of the invention, the display device further includes a front cover. The front cover is assembled to a surface of the hinge bracket back to rd the panel module.

In an embodiment of the invention, these hinge brackets are assembled in parallel on these first supports by a screw locking method or a hot-melting fixing method respectively.

In view of the above, the display device and its assembly method of the invention thin the internal space of the display device by simplifying the internal structure of the display device, e.g., integrating the hinge brackets or the reflector sheet with the fixing frame, so as to improve the structural thickness of the display device efficiently and still maintain the original structural strength of the display device.

### BRIEF DESCRIPTION OF THE DRAWINGS

FIG. 1 illustrates a rotating axis frame of a conventional display panel;

FIG. 2 illustrates an assembly perspective view of the first bracket and the first hinge of FIG. 1;

FIG. 3 illustrates a schematic view of the rotating axis frame of FIG. 1 assembled to a display panel;

FIG. 4 illustrates a perspective decomposition schematic view of observing a fixing frame towards a first direction according to a first embodiment of the invention;

FIG. 5 illustrates a perspective decomposition schematic view of observing a display module towards a second direction according to the first embodiment of the invention;

FIG. 6 illustrates a partial sectional view of the display module according to the first embodiment of the invention;

FIG. 7 illustrates a perspective decomposition schematic view of the fixing frame according to a second embodiment of the invention;

FIG. 8 illustrates a decomposition schematic view of the display module according to the second embodiment of the invention;

FIG. 9 illustrates a partial sectional view of the display module according to the second embodiment of the invention;

FIG. 10 illustrates a partial enlargement view of an area M1 of FIG. 7;

FIG. 11 illustrates a partial enlargement view of an area M2 of FIG. 7;

FIG. 12 illustrates a perspective decomposition schematic view of the display device according to the second embodiment of the invention;

FIG. 13 illustrates a flow chart of an assembly method of the display device according to the invention;

FIG. 14 illustrates a perspective decomposition schematic view of the display module according to a third embodiment of the invention;

FIG. 15 illustrates a partial sectional view of the display module according to the third embodiment of the invention; and

FIG. 16 illustrates a flow chart of the assembly method of the display device according to the third embodiment of the invention.

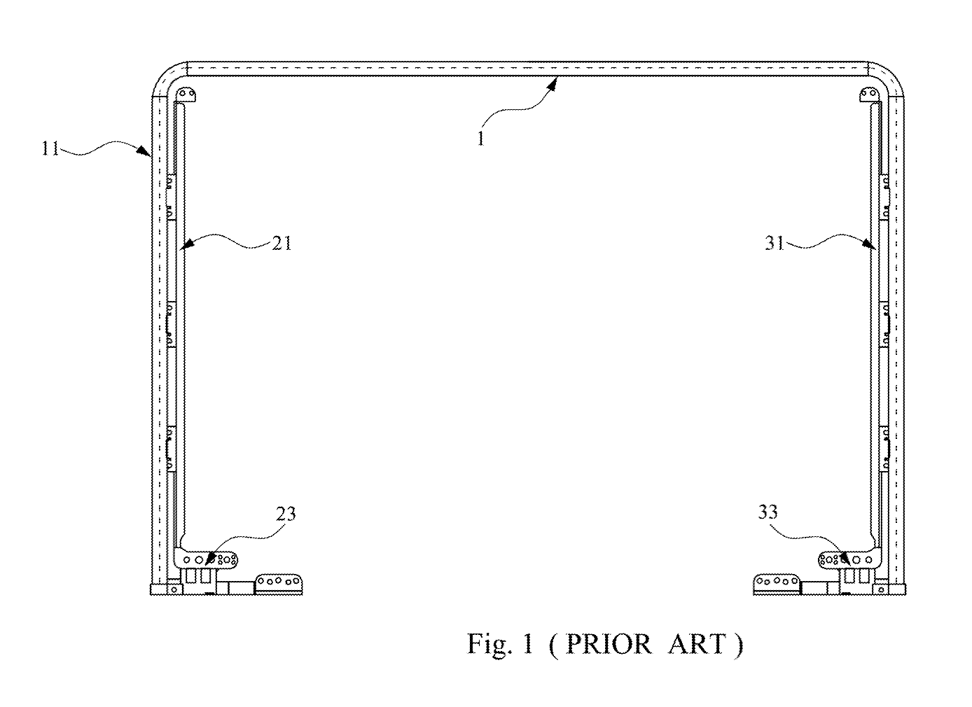

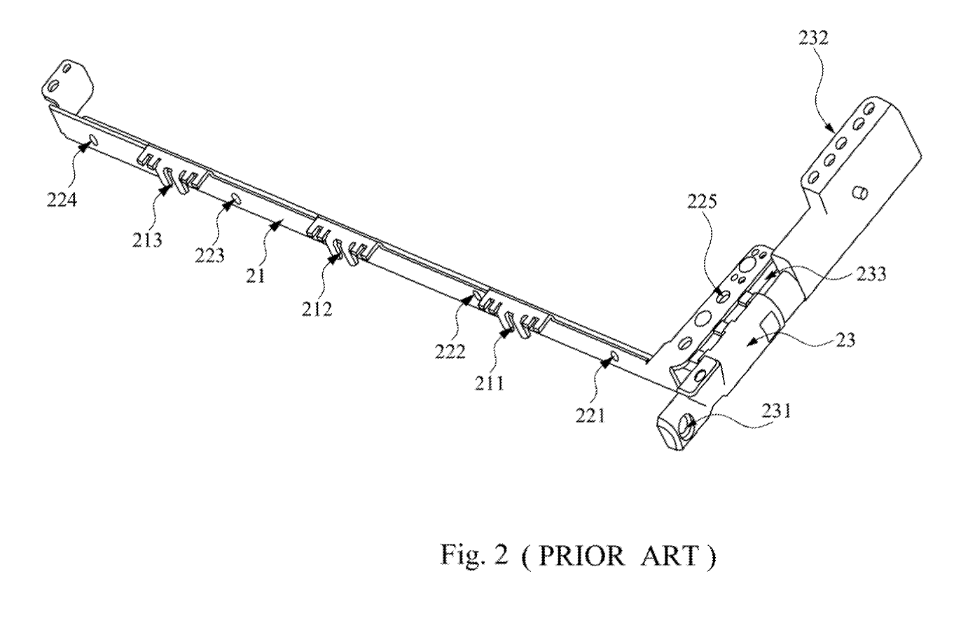

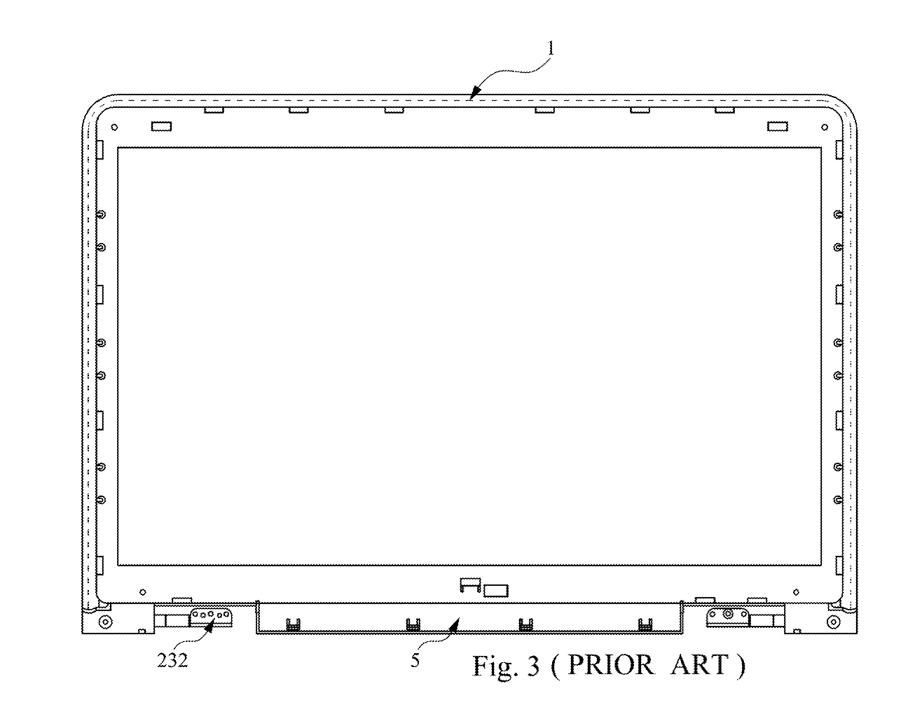

### DETAILED DESCRIPTION

A plurality of embodiments of the invention will be disclosed with reference to the drawings as follows. For the purpose of clear description, many practical details will be described together as follows. However, it should be understood that, these practical details shall not be used to limit the invention. In other words, in some embodiments of the invention, these practical details are unnecessary. In addition, in order to simplifying the drawings, some conventional and common structures and elements are illustrated in the drawings in a simple and schematic manner.

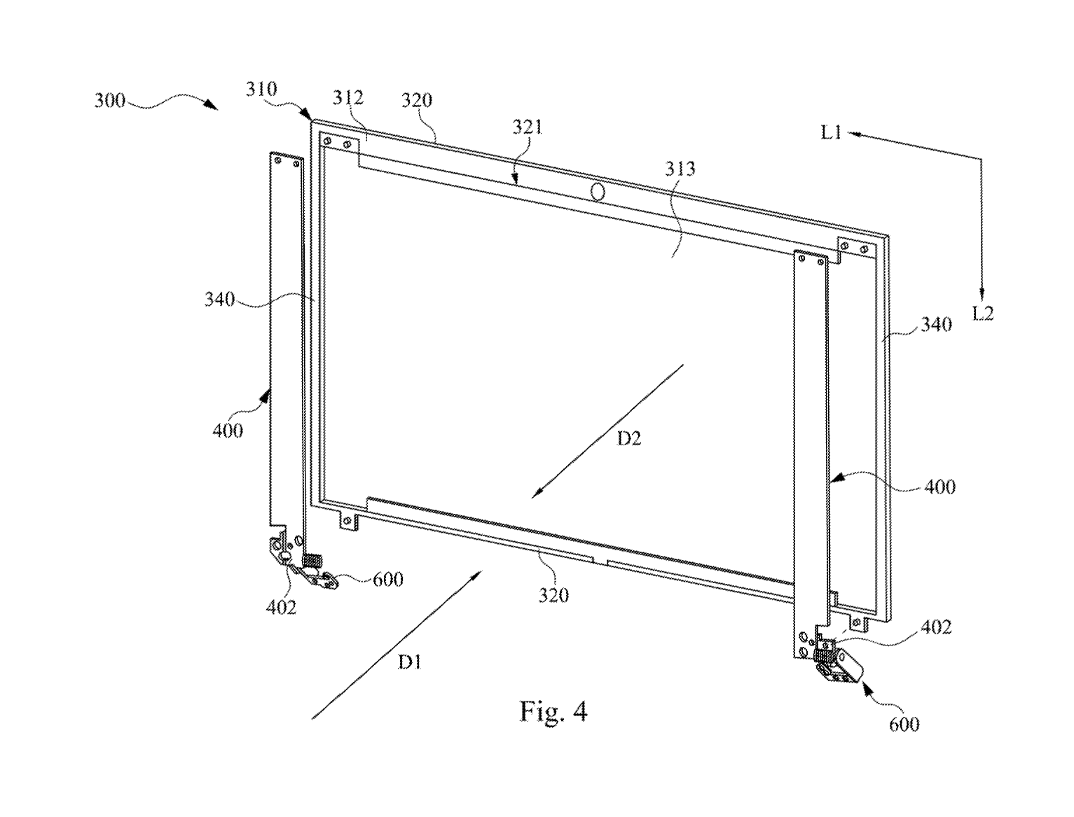

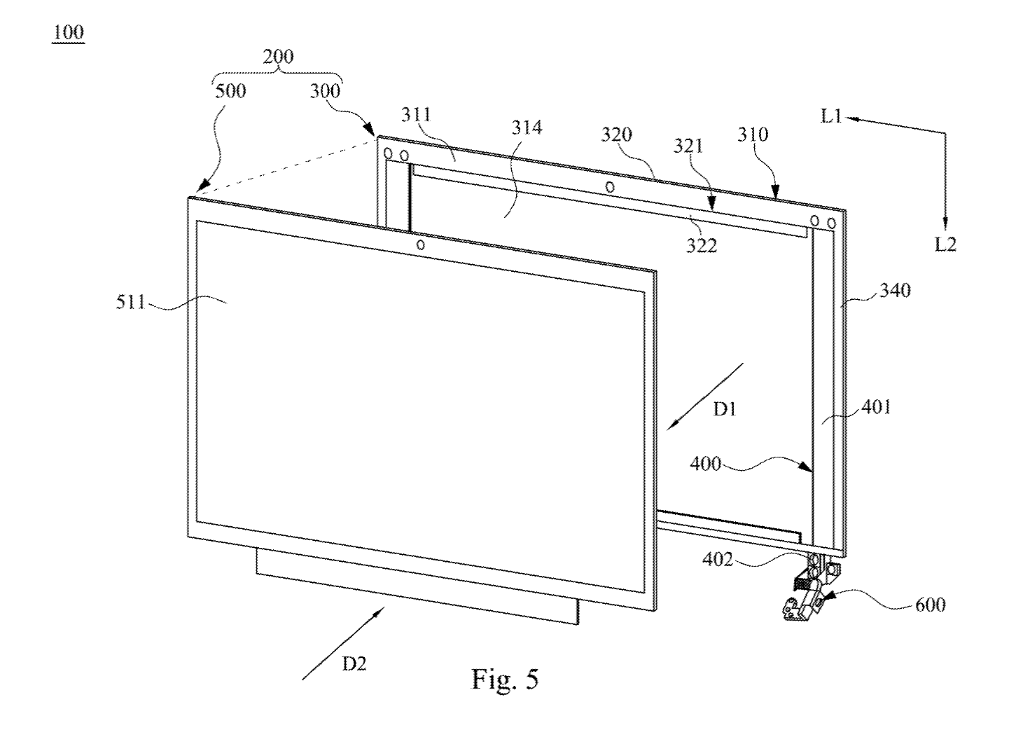

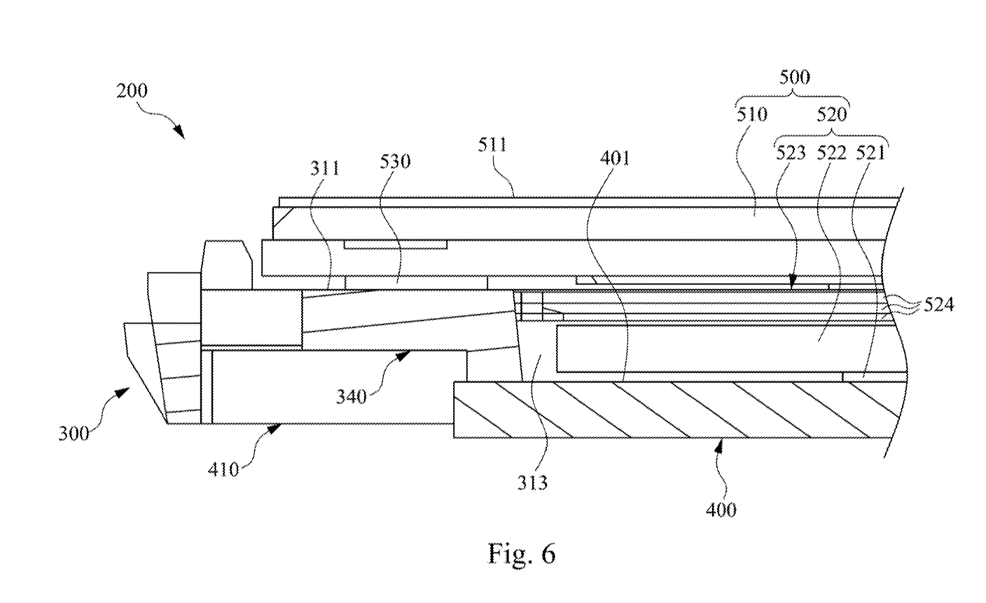

FIG. 4 illustrates a perspective decomposition schematic view of observing a fixing frame 300 towards a first direction D1 according to a first embodiment of the invention. FIG. 5 illustrates a perspective decomposition schematic view of observing a display module 200 towards a second direction D2 according to the first embodiment of the invention. FIG. 6 illustrates a partial sectional view of the display module 200 according to the first embodiment of the invention.

According to an embodiment of the invention, referring to FIGS. 4-6 at the same time, a display device 100 includes a display module 200 and two hinge elements 600. The display module 200 includes a fixing frame 300 and a panel module 500. The fixing frame 300 includes two first supports 320 and two hinge brackets 400. The two first supports 320 are configured in parallel. The two hinge brackets 400 are configured in parallel collectively assembled with these first supports 320 to be the fixing frame 300 and the two hinge brackets 400 and these first supports 320 work together to define a hollow portion 314 (FIG. 5). Each of the hinge brackets 400 includes a first placement surface 401 and a hinge contact portion 402. The hinge contact portion 402 is located on an end of the hinge bracket 400. The panel module 500 covers the hollow portion 314, and is secured on the fixing frame 300. A bottom surface of the panel module 500 is supported by these first placement surfaces 401.

The two hinge elements 600 are connected to these hinge contact portions 402 respectively used to connect a system main machine so that the display device 100 can be rotated over with relative to the system main machine. Thus, the internal space of the display device 100 is thinned by simplifying the internal structure of the display device 100 e.g., integrating the hinge brackets 400 with the fixing frame 300 into one, so as to improve the structural thickness of the display device 100 efficiently and still maintain the original structural strength of the display device 100.

The display module 200 of the invention is not limited to the panel module 500 having a backlight module 520 (e.g., a liquid crystal display (LCD) module) or the panel module without a backlight module, i.e., an active light-emitting display module (e.g., an organic light-emitting diode (OLEO)). Multiple embodiments will be disclosed as follows according to the above-mentioned description so as to further describe the technical means of the invention. However, the following embodiments are only illustrative for the specification and the invention is not limited to this.

Although the following embodiments are used for the panel module having the backlight module, they do not limit the scope of the invention. In addition, the display device of the invention is not limited to the application to the portable electronic devices (e.g., a notebook computer and a tablet computer) or the non-portable electronic devices (e.g., a desktop computer and a television device). Although the following embodiments are used for the notebook computer, they do not limit the scope of the invention.

According to the first embodiment of the invention, referring to FIGS. 4-6 at the same time, the fixing frame 300 of the display module 200 is substantially a collective assembly of a first frame body 310 and the two hinge brackets 400. The first frame body 310 is formed by the two first supports 320 and the two second supports 340 together. Each second support 340 is connected between the two first supports 320. A long axis direction L2 of each second support 340 is mutually orthogonal to a long axis direction L1 of each first support 320, and the two first supports 320 and the two second supports 340 collectively surround an opening 313 together. The two first supports 320 and the two second supports 340 can be molded by an integrated manner to manufacture the first frame body 310 or after being molded independently, they are assembled collectively to form the first frame body 310. The material of the first frame body 310 is not limited to plastic, metal or a combination of plastic and metal.

The first frame body 310 includes a first surface 311 and a second surface 312 opposite to each other. The second surface 312 of the first frame body 310 is opposite to the panel module 500, and the hinge brackets 400 are overlapped in parallel on the second surface 312 of the first frame body 310. Specifically, these hinge brackets 400 have a cylinder shape, are assembled to the second surface 312 of the first frame body 310 and assembled on the two first supports 320. One portion of each hinge bracket 400 extends outwards from one of the first frame bodies 310, and the portions of the two hinge brackets 400 extend towards the same direction. Each hinge contact portion 402 is located on the portion of each hinge bracket 400, assembled with a hinge element 600. The material of these hinge brackets 400 is not limited to plastic, metal or a combination of plastic and metal.

In addition, one inner edge of each first support 320 extending along the long axis direction L1 extends a flange 321 towards the hollow portion 314. Each of these flanges 321 has a second placement surface 322 thereon. It should be understood that, the second placement surface 322 and the first surface 311 of the first frame body 310 are in different plane heights. The second placement surface 322 and the first placement surface 401 are not limited to the necessary coexistence in the same plane height or different plane heights.

Referring to FIG. 6, the panel module 500 includes a display panel 510 and a backlight module 520. The display panel 510 includes a high strength transparent substrate (not shown). The display panel 510 is overlapped on the backlight module 520, and pasted onto the backlight module 520. Both the display panel 510 and the backlight module 520 are secured on the first frame body 310 so that a display surface 511 of the display panel 510 can be exposed from the first frame body 310. An plane area of the display panel 510 is greater than an plane area of the backlight module 520 so that the first surface 311 of the first frame body 310 can contact and support the edge of the display panel 510 extending out with relative to the backlight module 520. For example, the display panel 510 is pasted to the first surface 311 of the first frame body 310 through a pasting layer 530 and covers the opening 313 (including the hollow portion 314).

The backlight module 520 of the panel module 500 is contacted and supported by these second placement surfaces 322 and the first placement surfaces 401 together. Specifically, the backlight module 520 includes a reflector sheet 521, a light guide plate 522 and an optical film sheet set 523 in order. The reflector sheet 521 is directly contacted with each first placement surface 401 and each second placement surface 322 of the hinge brackets 400, and is supported by the two hinge brackets 400. The reflector sheet 521 is located between the first placement surface 401 and the light guide plate 522. The optical film sheet set 523 is located between the light guide plate 522 and the display panel 510. The backlight module 520 further includes a light source (such as a LED light bar, not shown) towards a light-receiving surface of the light guide plate 522 to emit lights. The optical film sheet set 523 can include multiple optical film sheets 524, for example, which can be diffusion film sheets, lens sheets, brightening sheets, compound optical films or a combination thereof. It should be described that, the invention is not limited to this and can be adjusted depending on the actual demand, e.g., omitting the light guide plate and using a direct-type backlight module.

However, the invention is not limited to this. The backlight module also can omit the reflector sheet so that the light guide plate is directly contacted with each first placement surface of the hinge brackets and is supported by the two hinge brackets.

In such a way, since each hinge bracket 400 crosses the opening 313 to be overlapped on the two first supports 320 adjacent to an inner edge of one of the second supports 340 so that these hinge brackets 400 are exposed in the opening 313. Therefore, when the panel module 500 is placed in the opening 313 of the fixing frame 300, these hinge brackets 400 can serve as a bracket used to support the panel module 500 (such as the backlight module 520). Not only can the original flange of the second support 340 be omitted but also the structural strength of the fixing frame 300 can be reinforced.

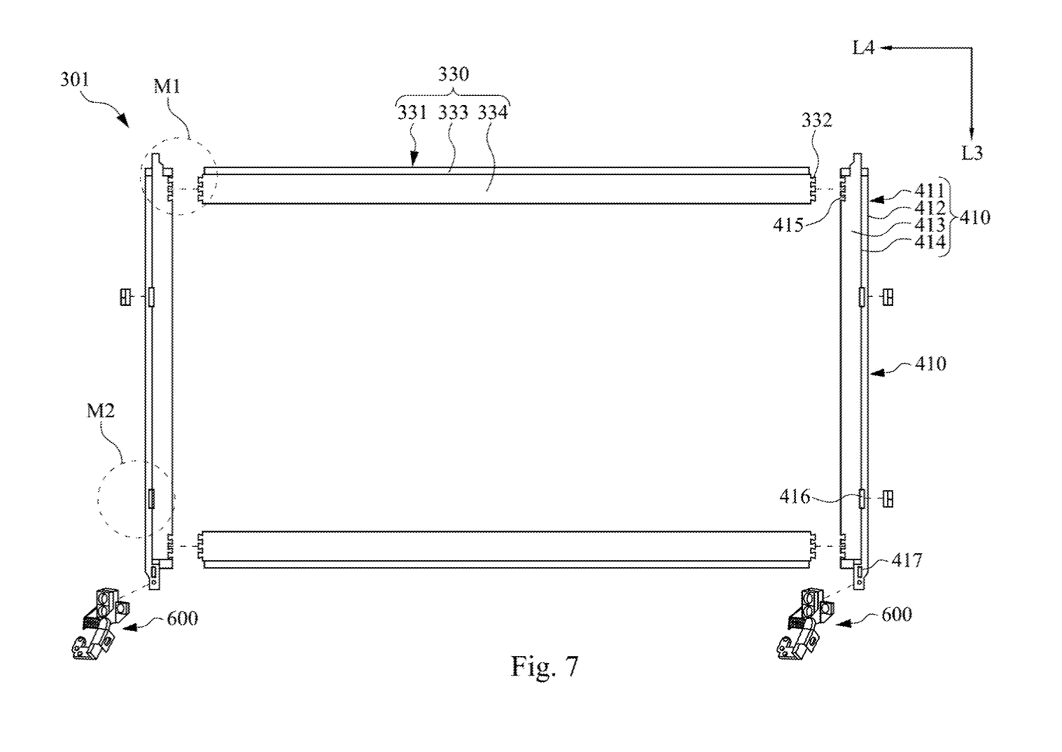

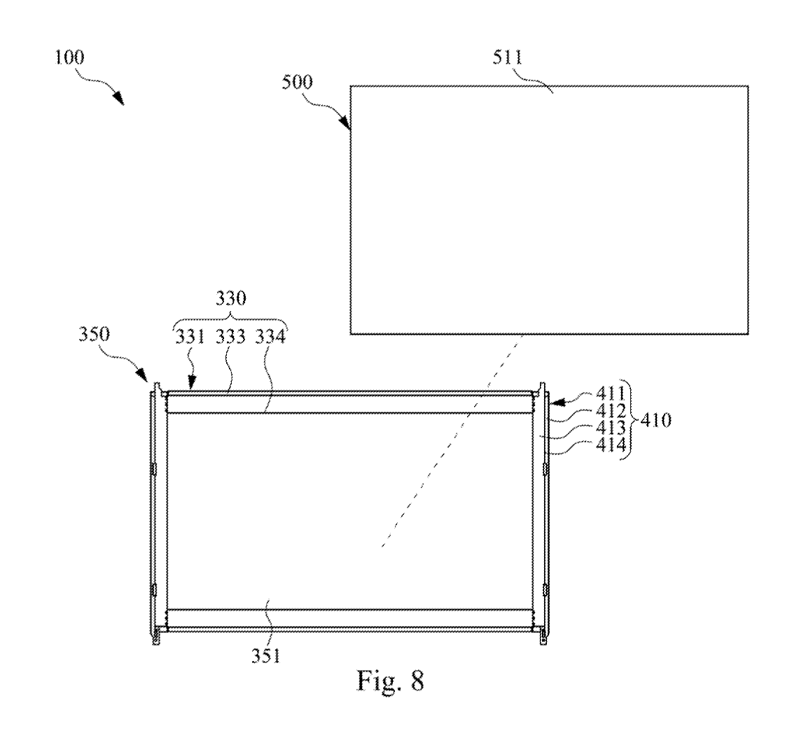

FIG. 7 illustrates a perspective decomposition schematic view of the fixing frame 301 according to a second embodiment of the invention. FIG. 8 illustrates a decomposition schematic view of the display module 200 according to the second embodiment of the invention.

According to the second embodiment of the invention, referring to FIGS. 7-8 at the same time, the fixing frame 301 of the display module 200 is substantially the second frame body 350 formed by collectively assembling the two first supports 330 and the two hinge brackets 410. Therefore, the second frame body 350 surrounds the above-mentioned hollow portion 351. The two first supports 330 and the two hinge brackets 410 are molded independently and then they are assembled to form the second frame body 350. The material of the two first supports 330 and the two hinge brackets 410 is not limited to plastic, metal or a combination of plastic and metal.

The main difference between the second embodiment and the first embodiment of the invention is that the second embodiment replaces the two second supports 340 of the first embodiment with the two hinge brackets 410 so that the second frame body 350 can be connected to the hinge element 600 directly, without adding the hinge brackets 410 of the first embodiment on the second frame body 350 additionally.

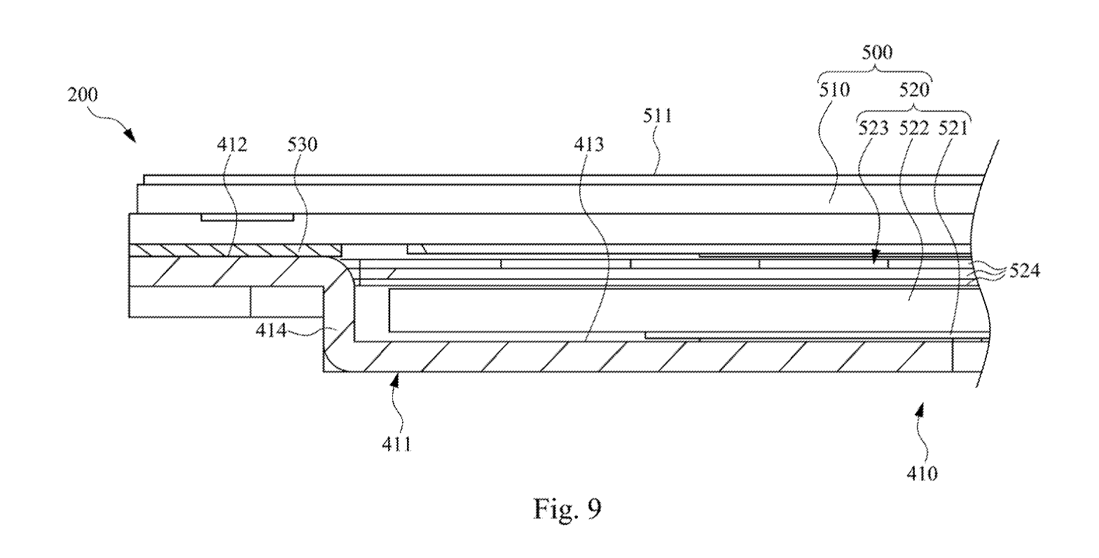

FIG. 9 illustrates a partial sectional view of the display module 200 according to the second embodiment of the invention. Specifically, referring to FIGS. 7 and 9, each hinge bracket 410 includes a first linear frame 411, a first high section differential surface 412 and a first low section differential surface 413. The first high section differential surface 412 is located on a side edge of the first linear frame 411 far away from the hollow portion 351. The first low section differential surface 413 is located on another side edge of the first linear frame 411 between the hollow portion 351 and the first high section differential surface 412. A long axis direction L3 of the first low section differential surface 413 is parallel to that of the first high section differential surface 412. The first low section differential surface 413 can be the above-mentioned first placement surface. An end of these first linear frames 411 is configured with a hinge contact portion 417 so as to assemble a hinge element 600 (referring to FIG. 4).

Referring to FIGS. 7 and 9, each first support 330 includes a second linear frame 331, a second high section differential surface 333 and a second low section differential surface 334. The second high section differential surface 333 is located on a side edge of the second linear frame 331 far away from the hollow portion 351. The second low section differential surface 334 is located on another side edge of the second linear frame 331 between the hollow portion 351 and the second high section differential surface 333. A long axis direction L4 of the second low section differential surface 334 is parallel to a long axis direction L4 of the second high section differential surface 333.

The composition of the panel module 500 is as described in the embodiment, which will not be described anymore herein. Since the plane area of the display panel 510 is greater than the plane area of the backlight module 520. The edge of the display panel 510 extending out with relative to the backlight module 520 can be contacted and supported by the first high section differential surface 412 and the second high section differential surface 333 (similar to the first high section differential surface 412) and the backlight module 520 can be abutted against and supported by the first low section differential surface 413 and the second low section differential surface 334 (similar to the first low section differential surface 413).

Specifically, the reflector sheet 521 is contacted with the first low section differential surface 413 and the second low section differential surface 334 (similar to the first low section differential surface 413) directly and is supported by the two hinge brackets 410 and the first supports 330. However, the invention is not limited to this. The backlight module 520 also can omit the reflector sheet 521 so that the light guide plate 522 is contacted with the hinge brackets 410 and the first supports 330 directly and is supported by the two hinge brackets 410 and the first supports 330.

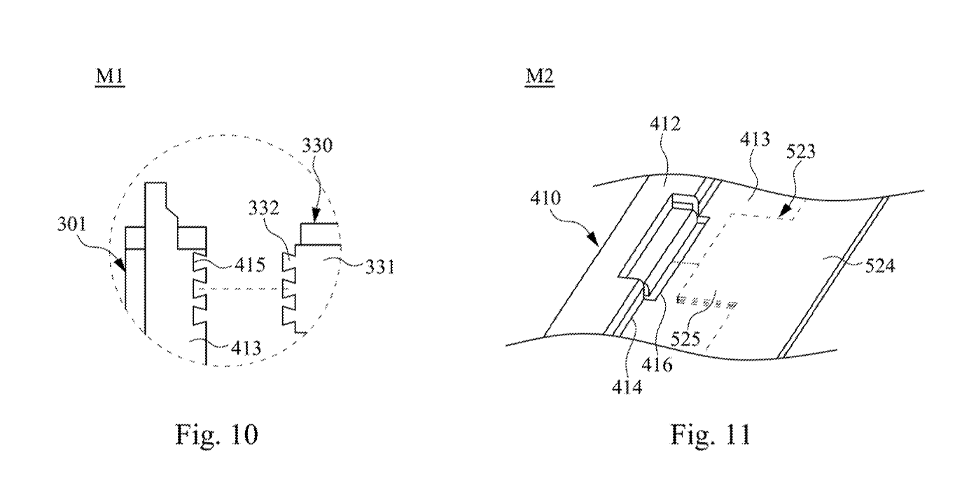

FIG. 10 illustrates a partial enlargement view of an area M1 of FIG. 7. Referring to FIGS. 7 and 10, each hinge bracket 410 further includes two first embedding portions 415. The two first embedding portions 415 are configured oppositely on a one side of the first low section differential surface 413. Each first support 330 further includes two second embedding portions 332. The two second embedding portions 332 are oppositely configured on two ends of the second linear frame 331. Each second embedding portion 332 is aligned with a first embedding portion 415 on an end of the second linear frame 331 and it can be just embedded into the first embedding portion 415.

For example, the first embedding portion 415 and the second embedding portion 332 embedded into each other are a dovetail tenon and a dovetail groove respectively. However, the invention is not limited to this and other conventional embedding means also fall into the scope of the invention. In addition, the two first supports and the two hinge brackets are not limited to forming the second frame body by embedding. The two first supports and the two hinge brackets also can form the second frame body by mutual overlapping.

FIG. 11 illustrates a partial enlargement view of an area M2 of FIG. 7. Referring to FIGS. 7 and 11, each hinge bracket 410 further includes a connection side wall 414 and a location open slot 416. The connection side wall 414 is located in the first linear frame 411 and is connected between the first high section differential surface 412 and the first low section differential surface 413. The location open slot 416 is located on the connection side wall 414 used to locate the optical film sheet set 523 of the backlight module 520. Since each optical film sheet 524 of the optical film sheet set 523 is configured with two nose portions 525 configured relatively and these nose portions 525 on the same side of these optical film sheets 524 all are aligned with each other, when the optical film sheet set 523 is configured, these nose portions 525 on two sides of these optical film sheets 524 are stretched into two location open slots 416 of each hinge bracket 410 to complete the location of these optical film sheets 524.

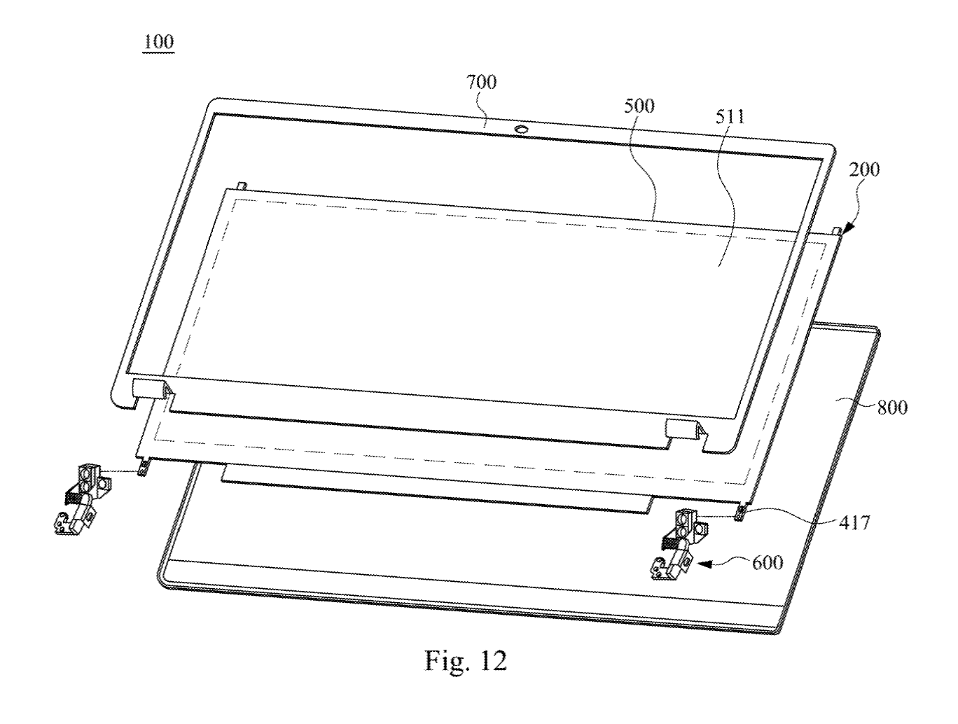

FIG. 12 illustrates a perspective decomposition schematic view of the display device 100 according to the second embodiment of the invention. Referring to FIG. 12, the display device 100 further includes a bezel frame 700 and a front cover 800. The bezel frame 700 is assembled on the display surface 511 of the panel module 500. The front cover 800 is assembled on a surface of the hinge bracket 410 back towards the panel module 500. In other words the display module 200 is configured between the bezel frame 700 and the front cover 800. In such a way, since the hinge bracket 410 has been integrated on the fixing frame 301, another hinge bracket 410 is not needed to configure in the front cover 800. In such a way, the internal space of the display device 100 can be thinned so as to improve the structural thickness of the display device 100 and still maintain the original structural strength of the display device 100.

Although the front cover 800 of FIG. 12 is used to describe the second embodiment of the invention, the front cover 800 of FIG. 12 also can be commonly used in the first embodiment so that the front cover 800 is assembled on a surface of the hinge bracket 410 back towards the panel module 500.

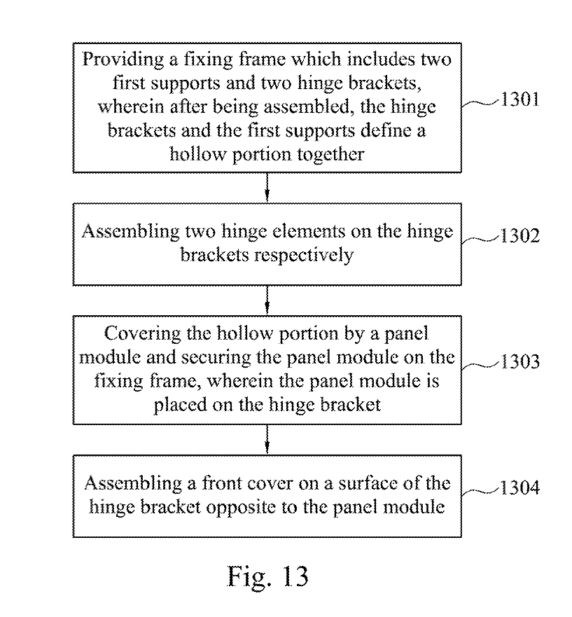

FIG. 13 illustrates a flow chart of an assembly method of the display device 100 according to the invention.

Referring to FIG. 13, the assembly method of the display device 100 of the invention includes the following steps.

In the step (1301), a fixing frame 300 is provided. The fixing frame 300 includes two first supports 320 and two hinge brackets 400. The hinge brackets 400 and the first supports 320 are collectively assembled to define a hollow portion 314 together. The fixing frame 300 can be the fixing frame 300 described in the above first embodiment or second embodiment. Then, in the step (1302), two hinge elements 600 are assembled on the hinge brackets 400 respectively. Next, in the step (1303), a panel module 500 is used to cover the hollow portion 314 and is secured on the fixing frame 300, wherein the panel module 500 is placed on the hinge bracket 400. In the step (1304), a front cover 800 is assembled on a surface of the hinge bracket 400 opposite to the panel module 500.

Referring to FIGS. 4-6 of the first embodiment, furthermore, the step (1301) further includes the following steps. A first frame body 310 is provided. The first frame body 310 is formed by two first supports 320 and two second supports 340 together. The first frame body 310 includes a first surface 311 and a second surface 312 opposite to each other. A long axial edge of the first support 320 extends a flange 321 towards the hollow portion 314. In addition, the step (1301) further includes the following steps. These hinge brackets 400 are overlapped in parallel on a surface of the first support 320 back towards the panel module 500, wherein a portion of each hinge bracket 400 extends from a support towards a direction far away from another support. This portion of each hinge bracket 400 has a hinge contact portion 402 thereon.

In multiple optional methods of the above-mentioned steps, these hinge brackets 400 can be assembled in parallel on the surface of these supports back towards the panel module 500 respectively by a screw locking method or a hot-melting fixing method. The above-mentioned screw locking method can be divided into: (1) manufacturing screw holes for the hinge bracket 400 and then locking screws in the screw holes of the hinge bracket 400 from the first surface 311 of the first frame body 310 through the first support 320; and (2) configuring embedded nails for the first support 320 and locking the screws in the embedded nails from the second surface 312 of the first frame body 310 through the hinge bracket 400.

Furthermore, the step (1302) further includes: assembling each hinge element 600 onto the hinge contact portion 402.

Furthermore, the step (1303) further includes the following steps. The backlight module 520 is placed on the flange 321 and the hinge bracket 400 and then the display panel 510 is placed on a side of the backlight module 520 and the first surface 311 of the first frame body 310.

Referring to FIGS. 7-12 of the second embodiment, furthermore, the step (1301) further includes the following steps. A side edge of each hinge bracket 410 includes two first embedding portions 415. Two opposite ends of each first support 330 include a second embedding portion 332 respectively. By embedding the first embedding portions 415 into the second embedding portions 332 respectively, the hinge bracket 410 and the first support 330 are collectively assembled to form the second frame body 350.

Furthermore, the step (1303) further includes the following steps. A backlight module 520 of the panel module 500 is placed on the first low section differential surface 413 of these hinge brackets 410 and the second low section differential surface 334 of these first supports 330. Then, a display panel 510 of the panel module 500 is placed on the first high section differential surface 412 of these hinge brackets 410 and the second high section differential surface 333 of these first supports 330 and a side of the backlight module 520.

Furthermore, in the step (1303), when the backlight module 520 is placed on the first low section differential surface 413 of these hinge brackets 410, the step further includes: stretching the nose portions 525 of multiple optical film sheets 524 of the backlight module 520 into the same location open slot 416 of the hinge bracket 410.

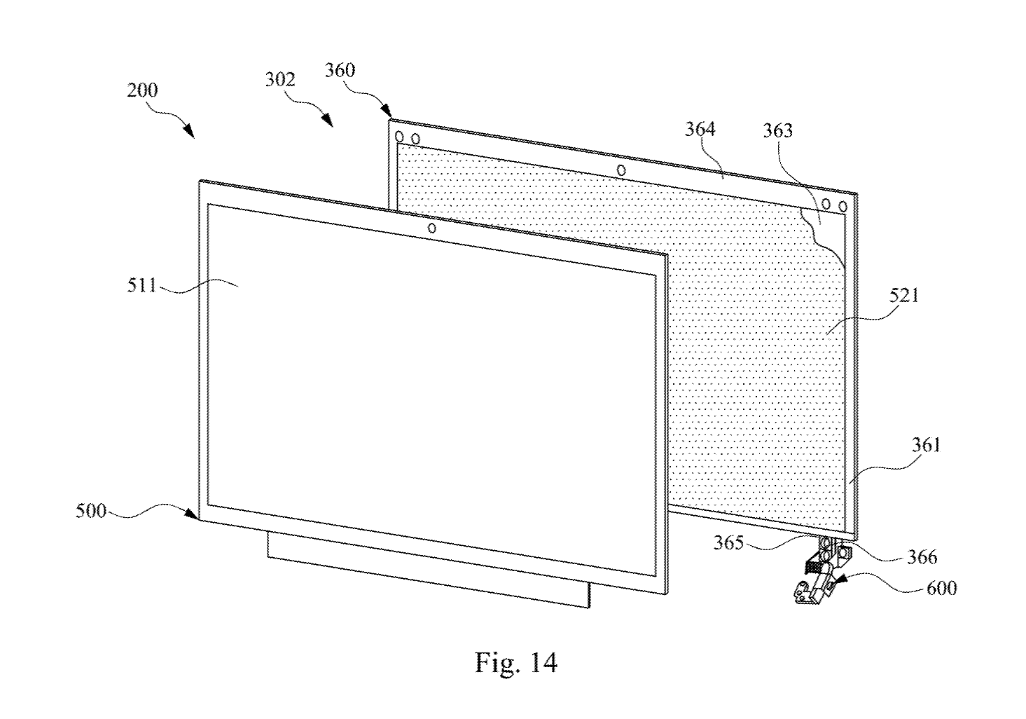

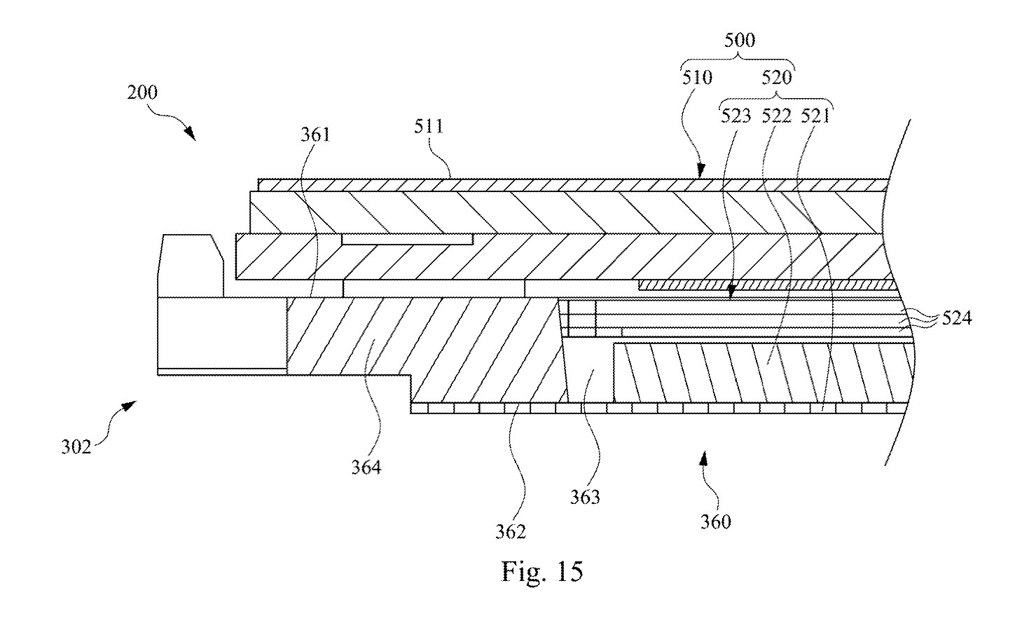

FIG. 14 illustrates a perspective decomposition schematic view of the display module 200 according to a third embodiment of the invention. FIG. 15 illustrates a partial sectional view of the display module 200 according to the third embodiment of the invention.

Referring to FIGS. 14 and 15, according to the display module 200 of the third embodiment of the invention, the fixing frame 302 of the display module 200 is substantially a third frame body 360 which includes an opening 363 and a surrounding portion 364 surrounding the opening 363. The surrounding portion 364 includes a first surface 361 and a second surface 362 opposite to each other. The material of the third frame body 360 is not limited to plastic, metal or a combination of plastic and metal.

Referring to FIG. 14, the panel module 500 includes a display panel 510 and a backlight module 520. The display panel 510 includes a high strength transparent substrate (not shown). The display panel 510 and the backlight module 520 are overlapped and pasted onto the backlight module 520. Both the display panel 510 and the backlight module 520 are secured on the third frame body 360 so that the display panel 510 can expose a display surface 511 from the third frame body 360. The plane area of the display panel 510 is larger than that of the backlight module 520 so that the first surface 361 of the third frame body 360 can be abutted against and support the edge of the display panel 510 extending out with relative to the backlight module 520. For example, the display panel 510 is pasted to the first surface 361 of the third frame body 360 through a pasting layer 530 and is filled into the opening 363.

The backlight module 520 includes the reflector sheet 521, the light guide plate 522 and the optical film sheet set 523 in order. The reflector sheet 521 is connected to the second surface 362 of the surrounding portion 364 directly to cover the opening 363 and is directly abutted against and supports the light guide plate 522 of the panel module 500. The optical film sheet set 523 is located between the light guide plate 522 and the display panel 510. The backlight module 520 further includes a light source (such as a LED light bar, not shown) towards a light-receiving surface of the light guide plate 522 to emit lights. The optical film sheet set 523 can include multiple optical film sheets 524, for example, diffusion film sheets, lens sheets, brightening sheets, combined optical films or a combination thereof. The material of the reflector sheet 521 is not limited to plastic, metal or a combination of plastic and metal.

In such a way, since the reflector sheet 521 is directly connected to the second surface 362 of the surrounding portion 364 of the fixing frame 302 to cover the opening 363, so that the reflector sheet 521 serves as the bracket supporting the light guide plate 522 directly, which not only improves the structural thickness of the display device 100 efficiently but also saves the material of the fixing frame 302, thereby reducing the manufacturing cost.

In addition, the fixing frame 302 further includes two extension ribs 365. The two extension ribs 365 are relatively configured on an outer edge of a side of the surrounding portion 364 back towards the opening 363 and the two extension ribs 365 extend towards the same direction far away from the opening 363. One end of each extension rib 365 has a hinge contact portion 366 which connects one of the above-mentioned hinge elements 600.

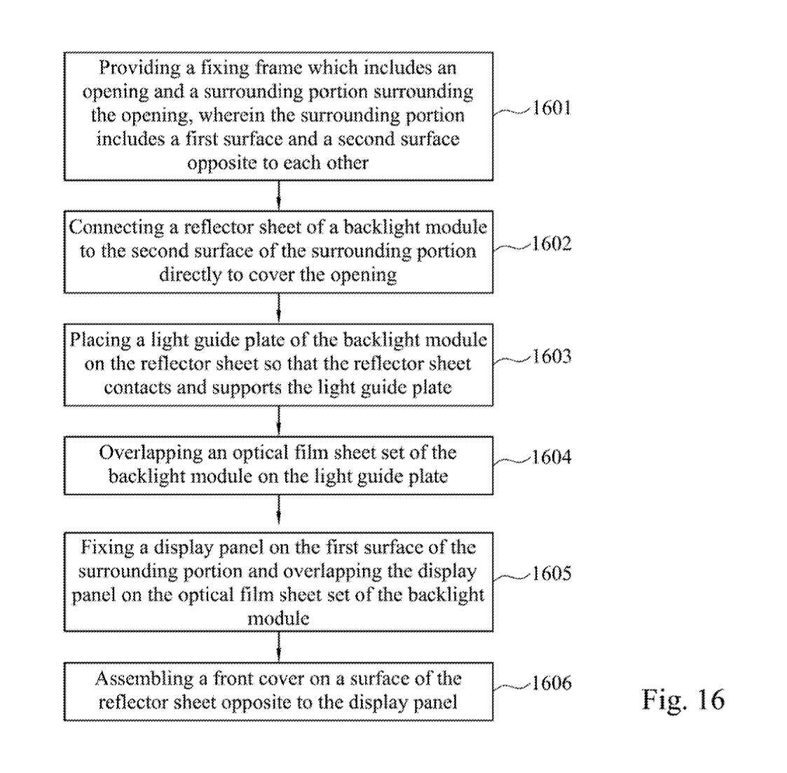

FIG. 16 illustrates a flow chart of the assembly method of the display device 100 according to the third embodiment of the invention.

Referring to FIG. 16, the assembly method of the display device 100 of the invention includes the following steps.

In the step (1601), a fixing frame 302 is provided. The fixing frame 302 includes an opening 363 and a surrounding portion 364 surrounding the opening 363. The surrounding portion 364 includes the first surface 361 and the second surface 362 opposite to each other. Then, in the step (1602), a reflector sheet 521 of a backlight module 520 is connected to the second surface 362 of the surrounding portion 364 directly to cover the opening 363. Next, in the step (1603), a light guide plate 522 of the backlight module 520 is placed on the reflector sheet 521 so that the reflector sheet 521 is abutted against and supports the light guide plate 522. Then, in the step (1604), an optical film sheet set 523 of the backlight module 520 is overlapped on the light guide plate 522. Next, in the step (1605), a display panel 510 is fixed on the first surface 361 of the surrounding portion 364 and is overlapped on the optical film sheet set 523 of the backlight module 520. Then, in the step (1606), a front cover 800 is assembled to a surface of the reflector sheet 521 opposite to the display panel 510.

Referring to FIGS. 14 and 15 of the third embodiment, furthermore, the step (1602) further includes the following steps. By an ultrasonic melting method, the reflector sheet 521 is connected to the second surface 362 of the surrounding portion 364 directly.

In view of the above, the display device and its assembly method of the invention thins the internal space of the display device by simplifying the internal structure of the display device, e.g., integrating the hinge brackets or the reflector sheet with the fixing frame, so as to improve the structural thickness of the display device efficiently and still maintain the original structural strength of the display device.

Although the invention has been disclosed with reference to the above embodiments, these embodiments are not intended to limit the invention.

Those of skills in the art can make various modifications and changes without departing from the spirit and scope of the invention. Therefore, the scope of the invention shall be defined by the appended claims.

What is claimed is:

1. A display device, comprising:
a fixing frame, comprising:
two first supports configured in parallel to each other; and
two hinge brackets configured in parallel to each other, collectively assembled with the first supports to be the fixing frame having a hollow portion therein, wherein each of the hinge brackets comprises a first placement surface and a hinge contact portion located on an end of the hinge bracket;
a panel module covering the hollow portion and being secured on the fixing frame, wherein a bottom surface of the panel module is supported by the first placement surfaces; and
two hinge elements connected to the hinge contact portions, respectively.

2. The display device of claim 1, wherein the panel module comprises a display panel and a backlight module overlapped on each other, and the backlight module is contacted with the first placement surfaces.

3. The display device of claim 2, wherein the fixing frame further comprises two second supports, the two first supports and the two second supports form a frame body together, the frame body comprises a first surface and a second surface opposite to each other, the first surface contacts and supports the display panel, and each of the hinge brackets is overlapped on the second surface of the frame body.

4. The display device of claim 3, wherein a portion of each of the hinge brackets extends outwards from the frame body,
wherein one of the hinge contact portions is located on the portion of the hinge bracket.

5. The display device of claim 3, wherein a long axial edge of each of the first supports extends a flange towards the hollow portion, each of the flanges is provided with a second placement surface, and the second placement surfaces and the first placement surfaces contact the backlight module, and support the backlight module,
wherein the second placement surface and the first placement surface coexist at the same plane height or different plane heights.

6. The display device of claim 2, wherein each of the hinge brackets comprises:
first linear frame;
a first high section differential surface located on a side edge of the first linear frame far away from the hollow portion; and
a first low section differential surface located on another side edge of the first linear frame, between the hallow portion and the first high section differential surface, wherein a long axis direction of the first low section differential surface is parallel to that of the first high section differential surface,
wherein the first high section differential surface contacts and supports the display panel, and the first low section differential surface is the first placement surface.

7. The display device of claim 6, wherein one of the hinge contact portions is located on an end of the first linear frame.

8. The display device of claim 6, wherein each of the first supports comprises:
a second linear frame;
a second high section differential surface located on a side edge of the second linear frame far away from the hollow portion; and
a second low section differential surface located on another side edge of the second linear frame, between the hollow portion and the second high section differential surface, wherein a long axis direction of the second low section differential surface is parallel to that of the second high section differential surface,
wherein the second high section differential surface contacts and supports the display panel, and the second low section differential surface is the second placement surface used to abut against and support the backlight module.

9. The display device of claim 8, wherein each of the hinge brackets further comprises:
two first embedding portions configured oppositely on one side of the first low section differential surface; and
each of the supports further comprises:
two second embedding portions oppositely configured on two ends of the second linear frame, wherein one of the second embedding portions is just embedded into one of the first embedding portions.

10. The display device of claim 9, wherein the first embedding portion and the second embedding portion which are embedded into each other respectively are a dovetail tenon and a dovetail groove.

11. The display device of claim 8, wherein each of the hinge brackets further comprises:
a connection side wall located in the first linear frame, and connected between the first high section differential surface and the first low section differential surface; and
a location open slot located on the connection side wall, used to locate multiple optical films of the backlight module.

12. The display device of claim 1 further comprising:
a front cover assembled on a surface of the hinge bracket back towards the panel module.

13. The display device of claim 1, wherein the hinge brackets are assembled in parallel on the first supports by a screw locking method or a hot-melting fixing method.

14. A display device, comprising:
a frame body, comprising:
two first supports configured in parallel to each other; and
two second supports configured in parallel to each other and collectively assembled with the first supports to be the frame body, wherein the frame body comprises a first surface and a second surface opposite to each other;
two hinge brackets overlapped on the second surface of the frame body respectively, wherein the two hinge brackets and the frame body work together to define a hollow portion, each of the hinge brackets is provided with a first placement surface and a hinge contact portion located on an end of the hinge bracket;
a panel module covering the hollow portion and being secured on the frame body, wherein a bottom surface of the panel module is supported by the first placement surfaces; and
two hinge elements connected to the hinge contact portions, respectively.

15. The display device of claim 14, wherein the panel module comprises a display panel and a backlight module overlapped on each other, and the backlight module is contacted with the first placement surfaces, wherein the first surface of the frame body contacts and supports the display panel.

16. The display device of claim 15, wherein a portion of each of the hinge brackets extends out of the frame body,
wherein one of the hinge contact portions is located on the portion of the hinge bracket.

17. The display device of claim 14, wherein each of the first supports further comprises two first embedding portions, each second support further comprises two second embedding portions and one of the second embedding portions is just embedded into one of the first embedding portions.

18. The display device of claim 17, wherein the first embedding portion and the second embedding portion embedded into each other are a dovetail tenon and a dovetail groove, respectively.

19. The display device of claim 14 further comprising:
a front cover assembled on a surface of the hinge bracket back towards the panel module.

20. The display device of claim 14, wherein the hinge brackets are configured in parallel and assembled to the frame body respectively by a screw locking method or a hot-melting fixing method.
